(19) United States
(12) Patent Application Publication
(10) Pub. No.: US 2026/0096480 A1
(43) Pub. Date: Apr. 2, 2026

(54) STACKED SEMICONDUCTOR APPARATUS, METHOD OF DETECTING FAULT, AND METHOD OF REPAIRING FAULT

(71) Applicant: ELECTRONICS AND TELECOMMUNICATIONS RESEARCH INSTITUTE, Daejeon (KR)

(72) Inventors: Jin Ho HAN, Daejeon (KR); Min-Seok CHOI, Daejeon (KR)

(73) Assignee: ELECTRONICS AND TELECOMMUNICATIONS RESEARCH INSTITUTE, Daejeon (KR)

(21) Appl. No.: 18/978,262

(22) Filed: Dec. 12, 2024

(30) Foreign Application Priority Data
Oct. 2, 2024 (KR) 10-2024-0133676

(51) Int. Cl. H01L 25/065; H01L 21/66; H01L 23/00; H01L 25/18; H10B 80/00

(52) U.S. Cl. CPC H10W 90/00; H10P 74/23; H10P 74/273; H10B 80/00; H10W 74/15; H10W 90/284; H10W 90/722; H10W 90/732

(57) ABSTRACT

A stacked semiconductor apparatus, which is formed by stacking a first die and a second die, includes the first die including a first test module configured to generate a test pattern and a plurality of transmission multiplexers, each of which one input receives the test pattern, the second die including a plurality of reception multiplexers and a second test module configured to control the plurality of reception multiplexers, and a connection part including a plurality of signal transmission members electrically connected to outputs of the plurality of transmission multiplexers and each connected to one input of the reception multiplexers, and a robust transmission member configured to transmit a signal between the first test module and the second test module, wherein the second test module transmits a signal, which is received by the reception multiplexer through the signal transmission member, to the first test module through the robust transmission member, and the first test module detects a fault of the signal transmission member by comparing the test pattern with the signal transmitted by the second test module through the robust transmission member.

### CROSS-REFERENCE TO RELATED APPLICATION

This application claims priority to and the benefit of Korean Patent Application Nos. 10-2023-0185900, filed on Dec. 19, 2023 and 10-2024-0133676, filed on Oct. 2, 2024, the disclosures of which are incorporated herein by reference in its entirety.

### BACKGROUND

### 1. Field of the Invention

The present disclosure generally relates to a stacked semiconductor apparatus, a method of detecting a fault, and a method of repairing a fault.

### 2. Discussion of Related Art

Nowadays, electronic devices require complex circuits to implement various functions, and the size of components used to implement these circuits is continuously decreasing. Accordingly, more elements may be formed on a single die than before to form circuits with a high degree of integration.

As the demand for miniaturized electronic devices increases, semiconductor packages should be designed more compactly, and there is a need to integrate elements with a high degree of integration. One of the solutions to these problems is to stack a plurality of functional semiconductor dies.

### SUMMARY OF THE INVENTION

A die and a die or a chiplet which is a module that performs some functions are stacked, and signal transmission members are used to transmit or receive data between the dies or between the die and the chiplet. However, a fault such as an unintended short circuit and/or open circuit may occur in the signal transmission member.

In order to improve the yield of a stacked semiconductor apparatus to be manufactured, it is necessary to be able to detect a fault and repair the detected fault.

The present invention is directed to providing a technology capable of detecting a fault to improve yield and a technology capable of repairing a detected fault.

According to an aspect of the present invention, there is provided a stacked semiconductor apparatus formed by stacking a first die (10) and a second die (20), the stacked semiconductor apparatus including the first die including a first test module configured to generate a test pattern and a plurality of transmission multiplexers, each of which one input receives the test pattern, the second die including a plurality of reception multiplexers and a second test module configured to control the plurality of reception multiplexers, and a connection part including a plurality of signal transmission members electrically connected to outputs of the plurality of transmission multiplexers and each connected to one input of the reception multiplexers and a robust transmission member configured to transmit a signal between the first test module and the second test module, wherein the second test module transmits a signal, which is received by the reception multiplexer through the signal transmission member, to the first test module through the robust transmission member, and the first test module detects a fault of the signal transmission member by comparing the test pattern with the signal transmitted by the second test module through the robust transmission member.

The transmission multiplexer may further receive an internal signal of the first die and may be controlled by the first test module to output the internal signal, and the reception multiplexer may further receive the internal signal and may be controlled by the second test module to output the internal signal to the second die.

The first die further may further include a bypass multiplexer to which outputs of the plurality of transmission multiplexers are provided and which is controlled by the first test module, the connection part may further include a bypass transmission member connected to an output of the bypass multiplexer, and the reception multiplexer may be connected to the bypass connection member to further receive an output of the transmission multiplexer. When the fault of the signal transmission member is detected, the first test module may control the bypass multiplexer to output an output signal of a transmission multiplexer, which is connected to the signal transmission member in which the fault has occurred, to the bypass transmission member, and the second test module may control the reception multiplexer to receive the output signal of the transmission multiplexer from the bypass transmission member. Each of the signal transmission member and the bypass transmission member may be one of a through-silicon via (TSV) and a bump, and the bypass transmission member may be disposed closer to a central portion of at least one of the first die and the second die than the signal transmission member.

The robust signal transmission member may be one of a TSV and a bump and may include a plurality of transmission members configured to transmit the same signal.

The first die may be a memory die, and the second die may be one of a logic die and a memory die.

According to another aspect of the present invention, there is provided a method of detecting a fault of a semiconductor apparatus including a first die and a second die which are stacked, the method including outputting, by the first die, a test pattern, which is formed by a first test module of the first die, through a plurality of signal transmission members, receiving, by the second die, a signal from the plurality of signal transmission members, outputting, by the second die, the received signal to the first test module through a robust transmission member, and detecting, by the second test module, a fault of the signal transmission member from the signal provided by the second die, wherein the robust transmission member includes a plurality of transmission members configured to transmit the same signal.

The first die may further include a plurality of transmission multiplexers to which the test pattern is input and which are controlled by the first test module, and the second die may further include a plurality of reception multiplexers to which a signal is input through the signal transmission member and which are controlled by the second test module. The outputting of the test pattern may include forming, by the first test module, the test pattern and outputting, by each of the transmission multiplexers, the test pattern to the signal transmission member. The receiving of the test pattern may include receiving, by each of the reception multiplexers, the signal from the signal transmission member and transmitting the signal received by the reception multiplexers to the second test module.

The detecting of the fault may be performed by comparing, by the first test module, the test pattern with a signal output by the second test module through the robust transmission member.

Each of the signal transmission member and the robust transmission member may be one of a TSV and a bump.

According to still another aspect of the present invention, there is provided method of repairing a stacking fault of a first die and a second die, the method including detecting, by a first test module, a fault of a plurality of signal transmission members configured to electrically connect the first die and the second die, controlling, by the first test module, a bypass multiplexer to output an output of a multiplexer connected to a signal transmission member having the detected fault through a bypass transmission member, and controlling, by a second test module, a reception multiplexer connected to the signal transmission member having the fault to output a signal provided through the bypass transmission member.

The first die may further include the first test module configured to form the test pattern and a plurality of transmission multiplexers to which the test pattern is input and which is controlled by the first test module, and the second die may further include a plurality of reception multiplexers, which are identical to the reception multiplexer, to which each signal is input through the plurality of signal transmission members and which are controlled by the second test module.

The detecting of the fault may include outputting, by the first test module of the first die, the test pattern to the plurality of signal transmission members, receiving, by the second test module of the second die, a signal from the plurality of signal transmission members, outputting the signal received by the second test module to the first test module through a robust transmission member, and detecting, by the first test module, the fault of the plurality of signal transmission members from the signal provided from the second test module. An output of at least some of the transmission multiplexers may be provided to an input of the bypass multiplexer, and the bypass multiplexer may be controlled by the first test module to provide an output to the bypass transmission member. Each of the reception multiplexers may further receive a signal provided through the bypass transmission member, and the second test module may control a reception multiplexer connected to the signal transmission member having the fault to output the signal provided through the bypass transmission member.

Each of the bypass transmission member and the transmission member may be one of a TSV and a bump, and the bypass transmission member may be disposed closer to a center of the first die and the second die than the signal transmission member.

The first test module and the second test module may be connected through a robust transmission member, and the robust transmission member may include a plurality of transmission members configured to transmit the same signal.

### BRIEF DESCRIPTION OF THE DRAWINGS

The above and other objects, features, and advantages of the present invention will become more apparent to those of ordinary skill in the art by describing exemplary embodiments thereof in detail with reference to the accompanying drawings, in which:

FIG. 1 is a cross-sectional view illustrating an outline of a semiconductor apparatus including a first die and a second die which are stacked according to the present embodiment;

FIG. 2 is a schematic plan view illustrating an example of a first die and a second die which are stacked;

FIG. 3 is a view illustrating an example in which data communication is performed between a first die and a second die in a semiconductor apparatus according to the present embodiment;

FIG. 4 is a schematic flowchart illustrating a method of testing a semiconductor apparatus including a first die and a second die which are stacked according to the present embodiment;

FIG. 5 is a view illustrating a process of detecting a fault when the fault has occurred in a signal transmission member;

FIG. 6 is a flowchart illustrating an outline of a method of repairing a stacking fault of a first die and a second die according to the present embodiment; and

FIG. 7 is a view illustrating a repair of a fault when the fault has occurred in a signal transmission member.

### DETAILED DESCRIPTION OF EXEMPLARY EMBODIMENTS

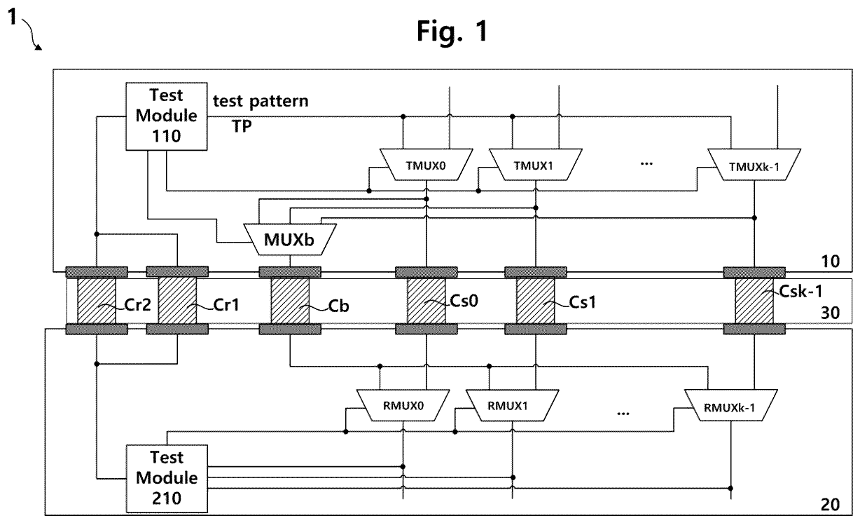

Hereinafter, the present embodiment will be described with reference to the accompanying drawings. FIG. 1 is a cross-sectional view illustrating an outline of a semiconductor apparatus 1 including a first die 10 and a second die 20 which are stacked according to the present embodiment. Referring to FIG. 1, the semiconductor apparatus 1 of the present embodiment is formed by stacking the second die 20 and the first die 10, and the first die 10 and the second die 20 are connected through a connection part 30 to transmit and receive an electric signal.

The first die 10 and the second die 20 may be semiconductor dies, and for example, may be a semiconductor die such as a silicon die or gallium-arsenide (Ga—As) die. In addition, the first die 10 and the second die 20 may each be a memory die in which a memory for storing data is formed, a logic die in which a logic circuit for performing an operation on data is formed, a network-on-chip (NoC) die which performs a network operation, or a system-on-chip die (SoC) in which a system is formed, but the present invention is not limited thereto. That is, the semiconductor apparatus 1 of the present embodiment may be formed by stacking heterogeneous dies such as a logic die and a memory die, or a memory die and a NoC die. However, it is not excluded that the semiconductor apparatus 1 of the present embodiment is formed by stacking homogeneous dies such as logic and logic dies or memory and memory dies.

In the present embodiment, a die is a basic component of an integrated circuit (IC) and may be a semiconductor block on which an IC is manufactured, and this term may be used as a term that includes a chiplet that performs some functions of an IC constituting a system by collaborating with other elements within a package.

The connection part 30 transmits and receives power and signals between the stacked first die 10 and second die 20. In the illustrated embodiment, the connection part 30 may include a plurality of signal transmission members Cs that transmit a signal between transmission multiplexers TMUX of the first die 10 and reception multiplexers RMUX of the second die 20, a bypass transmission member Cb that transmits a signal by bypassing the signal transmission member Cs in which a fault has occurred, and robust transmission members Cr1 and Cr2 that transmit a signal between a first test module 110 of the first die 10 and a second test module 210 of the second die 20. In one embodiment, the signal transmission member may include one of a through-silicon via (TSV) passing through a die and a bump.

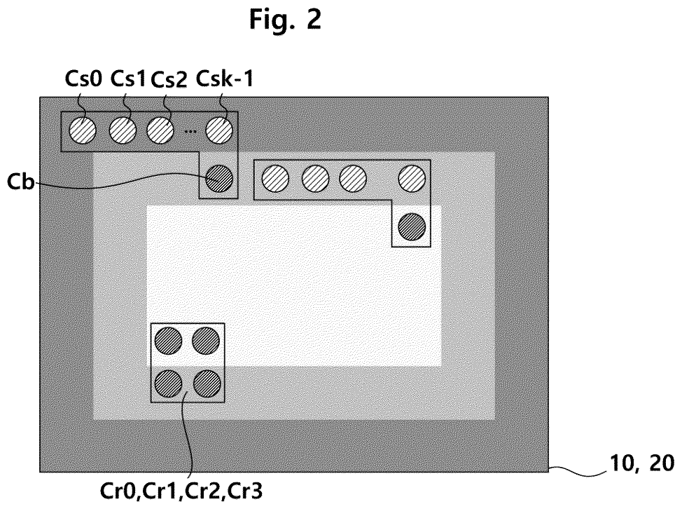

FIG. 2 is a schematic plan view illustrating an example of the stacked first die 10 and second die 20. In FIG. 2, it is illustrated that the darker an area, the more severe the distortion. As shown, it can be seen that the closer to a central portion of the first die 10 and the second die 20, the less physical distortion there is of a die, and conversely, the closer to a peripheral portion, the greater the physical distortion of the die. Accordingly, the closer the transmission members are to a peripheral portion, the greater a frequency of a fault while stacking the first die 10 and the second die 20 due to physical distortion of the die.

In such a case, when a fault occurs in signal transmission members Cs0, Cs1, Cs2, . . . , and Csk-1 disposed at a peripheral portion, a probability of fault repair may be improved by arranging the bypass transmission member Cb, which may bypass the signal transmission members in which a fault has occurred, to be closer to a central portion than the signal transmission members Cs0, Cs1, Cs2, . . . , and Csk-1. In addition, as will be described below, a plurality of robust transmission members Cr0, Cr1, Cr2, and Cr3 that receive a signal through communication between the first test module and the second test module may transmit a plurality of signals which are the same.

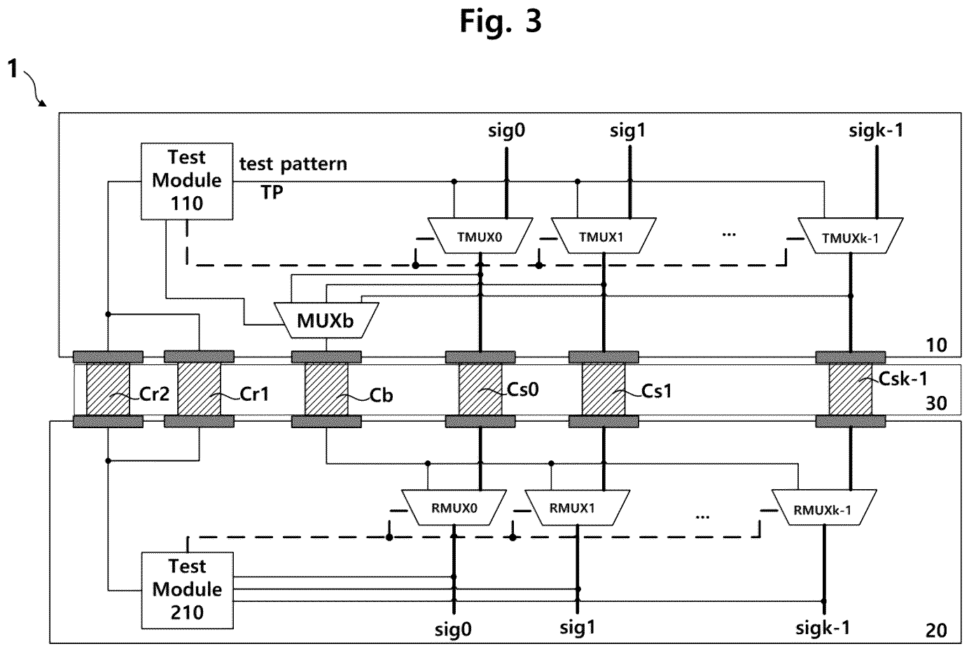

FIG. 3 is a view illustrating an example in which data communication is performed between the first die 10 and a second die 20 in the semiconductor apparatus 1 according to the present embodiment. Referring to FIG. 3, signals sig0, sig1, . . . , and sigk-1 to be transmitted from the first die 10 are provided to one inputs of transmission multiplexers TMUX0, TMUX1, . . . , and TMUXk-1.

The test module 110 positioned in the first die 10 provides a control signal such that the transmission multiplexers TMUX0, TMUX1, . . . , and TMUXk-1 output the signals sig0, sig1, . . . , sigk-1 provided to the one inputs thereof. The signals sig0, sig1, . . . , and sigk-1 output from the transmission multiplexers TMUX0, TMUX1, . . . , and TMUXk-1 may be transmitted to the second die 20 through the signal connection members Cs1, Cs2, . . . , and Csk-1, respectively.

One input of each of reception multiplexers RMUX0, RMUX1, . . . , and RMUXk-1 of the second die 20 is connected to the signal connection members Cs1, Cs2, . . . , and Csk-1. The second test module 210 of the second die 20 may provide a control signal to transmit a signal from the first die 10 to the second die 20 such that a signal provided to one input of each of the reception multiplexers RMUX0, RMUX1, . . . , and RMUXk-1 is output.

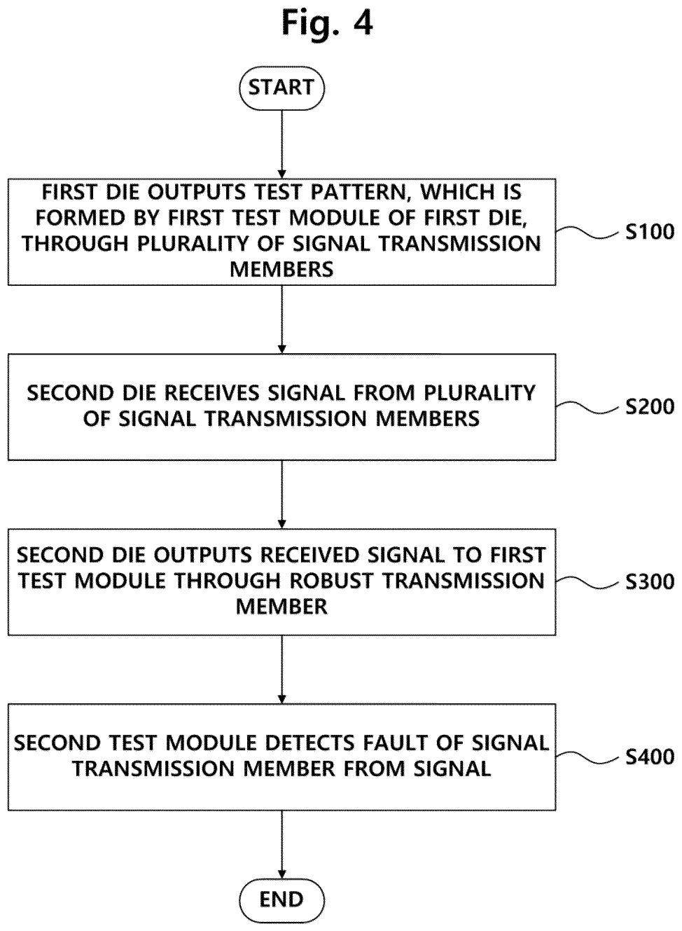

FIG. 4 is a schematic flowchart illustrating a method of testing the semiconductor apparatus including the first die and the second die which are stacked according to the present embodiment. Referring to FIG. 4, the method of testing the semiconductor apparatus including the stacked first die 10 and the second die 20 includes operation S100 of outputting, by the first die 10, a test pattern TP, which is formed by the first test module 110 of the first die 10, through a plurality of signal transmission members Cs0, Cs1, . . . , and Csk-1, operation S200 of receiving, by the second die 20, a signal from the plurality of signal transmission members Cs0, Cs1, . . . , and Csk-1, operation S300 of outputting, by the second die 20, the received signal through robust transmission members Cr1 and Cr2 to the first test module 110, and operation S400 of detecting, by the first test module 110, a fault of the signal transmission member from the signal provided by the second die 20.

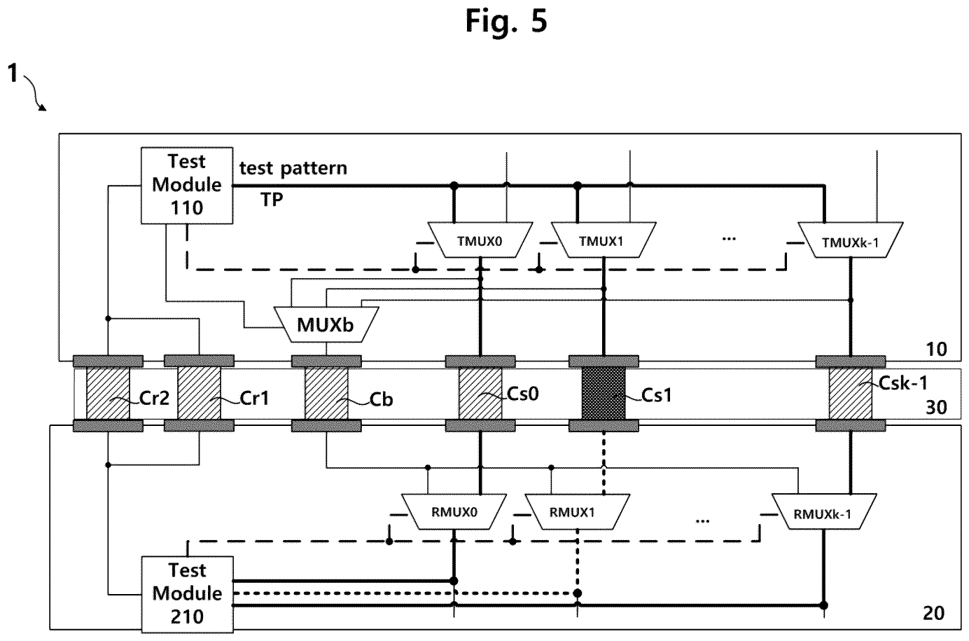

As shown in FIG. 5, the signal transmission member Cs1 in which a fault has occurred is shown darkly shaded. Referring to FIGS. 4 and 5, the first test module 110 forms and provides the test pattern TP to the other input of the transmission multiplexers TMUX0, TMUX1, . . . , and TMUXk-1.

In one embodiment, different types of information may be added to the test pattern TP formed and output by the first test module 110 according to the signal transmission members that are provided. As another example, the test pattern TP formed and output by the first test module 110 may be the same test pattern for each signal transmission member.

The first test module 110 controls the transmission multiplexers TMUX0, TMUX1, . . . , and TMUXk-1 such that each of the transmission multiplexers TMUX0, TMUX1, . . . , and TMUXk-1 outputs the test pattern TP provided as the other input. Accordingly, the first die 10 outputs the test pattern TP, which is formed by the first test module 110, through the plurality of signal transmission members Cs0, Cs1, . . . , and Csk-1 (S100).

The reception multiplexers RMUX0, RMUX1, . . . , and RMUXk-1 of the second die 20 receive a signal from the plurality of signal transmission members Cs0, Cs1, . . . , and Csk-1. In one embodiment, the signal transmission members Cs0 and Csk-1, in which a fault has not occurred, provide the provided signal to the reception multiplexers RMUX0 and RMUXk-1.

A fault occurring in the signal transmission member Cs1 may cause the formation of an open circuit or an increase in a resistance value due to a break of the signal transmission member Cs1, an increase in capacitance due to an unintended short circuit fault or the like (FIG. 5 is a view illustrating a process of detecting a fault occurring in the signal transmission member Cs1). Such a fault may cause an increase in signal delay time, an unintended decrease in signal amplitude or the like. The signal transmission member Cs1 provides the provided signal to the other input of the reception multiplexer RMUX1. The second test module 210 included in the second die 20 provides a control signal such that the signal provided to the other input of the transmission multiplexer TMUX0, TMUX1, . . . , and TMUXk-1 is output (S200).

The second test module 210 outputs the received signal received through the robust transmission members Cr1 and Cr2 (S300) to the first test module 110. As shown, the robust transmission members Cr1 and Cr2 may include a plurality of transmission members transmitting the same signal.

Even when a fault occurs in one of the transmission members constituting the robust transmission members Cr1 and Cr2, since a redundant transmission member transmits a signal, the robust transmission members operate robustly towards a fault. Although an embodiment in which two transmission members constitute the robust transmission members Cr1 and Cr2 is shown, this is merely an example, and as shown in FIG. 2 above, two or more transmission members may be included. Furthermore, although two adjacent transmission members are illustrated as constituting the robust transmission members Cr1 and Cr2, this is also merely an example, and the two transmission members may be positioned to be spaced apart from each other. Further, in a similar manner to the bypass transmission member described below, the transmission members constituting the robust transmission members may be positioned at a central portion of the first die and the second die.

Using the robust transmission members as provided in an example, a signal reflecting a fault among the signal transmission members Cs0, Cs1, . . . , and Csk-1 between the first die 10 and the second die 20 may be provided to the first test module 110 providing the test pattern TP.

The first test module 110 detects the fault of the signal transmission member from the signal provided by the second die 20 (S400). The first test module 110 receives a signal from the second test module 210 of the second die 20 and compares the received signal with the test pattern TP to determine whether the signal transmission members Cs0, Cs1, . . . , and Csk-1 are faulty.

As provided in the above-described embodiment, the test pattern TP provided by the first test module 110 may include information corresponding to a state of the signal transmission member transmitting a signal. Accordingly, the first test module 110 may receive the test pattern TP, which is output by the second test module 210, through the robust members Cr1 and Cr2, detect an abnormal delay time, an abnormal amplitude reduction, non-transmission of a signal, etc., and detect a signal transmission member in which a fault has occurred.

In another embodiment, the test pattern TP provided by the first test module 110 may not include information corresponding to the signal transmission member transmitting a signal. However, the second test module 210 outputs a signal that has been received to the first test module 110 through the robust transmission members Cr1 and Cr2 according to a preset order. The first test module 110 may detect an abnormal delay time, an abnormal amplitude reduction, non-transmission of a signal, etc. from the signal that has been received and may detect a signal transmission member in which a fault has occurred.

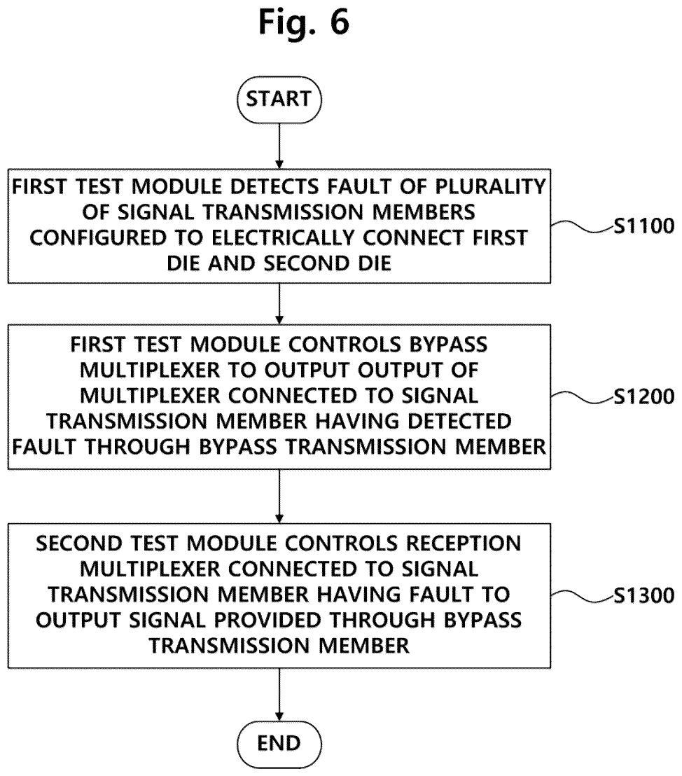

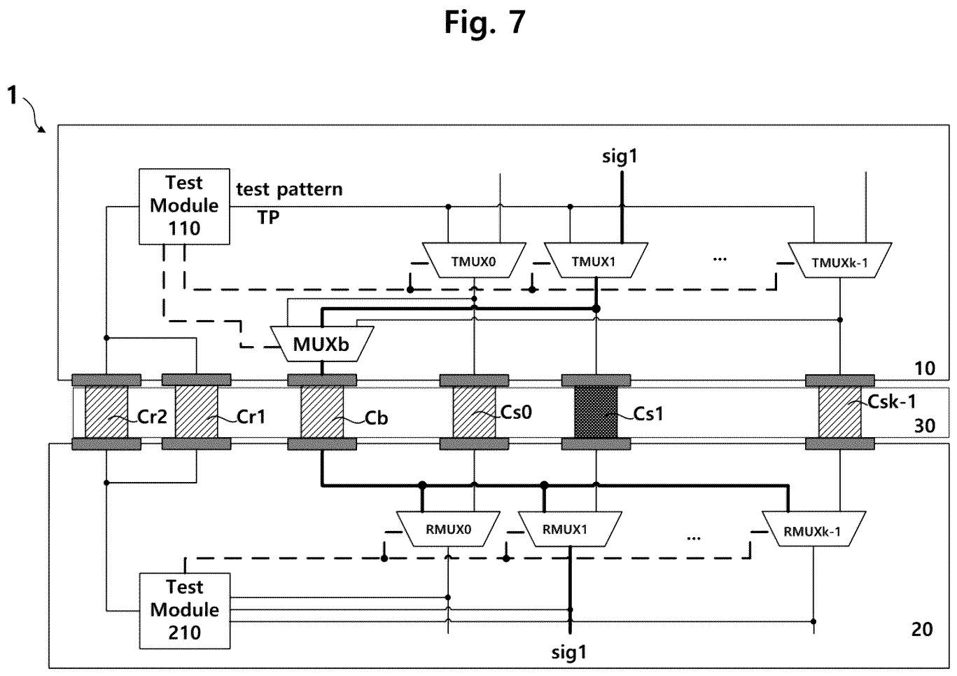

Hereinafter, a method of repairing a stacking fault of the first die 10 and the second die 20 according to the present embodiment will be described with reference to FIGS. 6 and 7. However, descriptions of elements identical or similar to those of the embodiments described above may be omitted for the sake of clarity and brevity. FIG. 6 is a flowchart illustrating an outline of the method of repairing the stacking fault of the first die 10 and the second die 20 according to the present embodiment. Referring to FIG. 6, the method of repairing the stacking fault of the first die 10 and the second die 20 according to the present embodiment includes operation S1100 of detecting, by the first test module 110, a fault of the plurality of signal transmission members electrically connecting the first die 10 and the second die 20, operation S1200 of controlling, by the first test module 110, the bypass multiplexer MUXb to output an output of the multiplexer connected to the signal transmission member Cs1 having the detected fault through the bypass transmission member Cb, and operation S1300 of controlling, by the second test module 210, the reception multiplexer RMUX1 connected to the signal transmission member Cs1 having the fault to output a signal provided through the bypass transmission member Cb.

FIG. 7 is a view illustrating repairing a fault when the fault has occurred in a signal transmission member. As in the embodiment described above, the signal transmission member Cs1 in which a fault has occurred is shown with a dark shade. Referring to FIGS. 6 and 7, the first test module 110 detects the fault of the plurality of signal transmission members electrically connecting the first die 10 and the second die 20 (S1100). As described above, an operation of detecting the fault of the plurality of signal transmission members Cs0, Cs1, . . . , and Csk-1 may be performed through operation S100 of outputting, by the first die 10, a test pattern TP, which is formed by the first test module 110 of the first die 10, through the plurality of signal transmission members Cs0, Cs1, . . . , and Csk-1, operation S200 of receiving, by the second die 20, a signal from the plurality of signal transmission members Cs0, Cs1, . . . , and Csk-1, operation S300 of outputting, by the second die 20, the received signal through the robust transmission members Cr1 and Cr2 to the first test module 110, and operation S400 of detecting, by the first test module 110, a fault of the signal transmission member from the signal provided by the second die 20.

The first test module 110 controls the bypass multiplexer MUXb to output an output of the transmission multiplexer TMUX1 connected to the signal transmission member Cs1 having the detected fault through the bypass transmission member Cb (S1200). In the illustrated embodiment, an output of a plurality of transmit multiplexers TMUX0, TMUX1, . . . , and TMUXk-1 is provided to an input of the bypass multiplexer MUXb. Although an embodiment in which an output of k transmit multiplexers TMUX0, TMUX1, . . . , and TMUXk-1 is input into a single bypass multiplexer MUXb is shown, in other embodiments not illustrated, the first die and the second die may include a plurality of bypass multiplexers.

In the illustrated embodiment, the bypass multiplexer MUXb transmits a signal through the bypass transmission member Cb described above. In the illustrated embodiment, the bypass transmission member Cb is illustrated together with the plurality of signal transmission members Cs0, Cs1, . . . , and Csk-1, but in order to secure robustness of signal transmission between the first die 10 and the second die 20 through the bypass transmission member Cb, the bypass transmission member Cb may be positioned closer to a central portion of the first die 10 and the second die 20 than the plurality of signal transmission members Cs0, Cs1, . . . , and Csk-1.

Next, the second test module 210 controls the reception multiplexer RMUX1 connected to the signal transmission member Cs1 having the fault to output the signal provided through the bypass transmission member Cb (S1300). An embodiment in which a single bypass transmission member Cb is provided to an input of a k number of reception multiplexers RMUX0, RMUX1, . . . , and RMUXk-1 is illustrated. However, in other embodiments not shown, the connection part 30 may include a plurality of bypass transmission members which may be provided to an input of a plurality of reception multiplexers.

In the illustrated embodiment, the second test module 210 provides a control signal to the reception multiplexer RMUX1 such that the reception multiplexer RMUX1 connected to the signal transmitting element Cs1 having the fault outputs the signal provided through the bypass transmission member Cb.

Even when a fault occurs in the signal transmission member Cs1 as provided in the illustrated embodiment, a signal may be bypassed and transmitted through the bypass transmission member Cb, thereby improving the yield of the semiconductor apparatus 1.

According to the present embodiment, a fault of a stacked semiconductor apparatus can be detected, and the detected fault can be repaired, thereby providing an advantage in improving the yield of the stacked semiconductor apparatus. Although embodiments shown in the drawings are described as a reference for helping understanding of the present disclosure, they are embodiments for implementation and merely exemplary, and those skilled in the art will understand that various modifications and equivalents are made possible therefrom. Accordingly, the true technical scope of the present disclosure should be defined by the appended claims.

According to the present embodiment, a fault of a stacked semiconductor apparatus can be detected, and the detected fault can be repaired, thereby providing an advantage in improving the yield of the stacked semiconductor apparatus.

What is claimed is:

1. A stacked semiconductor apparatus formed by stacking a first die (10) and a second die (20), the stacked semiconductor apparatus comprising:
the first die including a first test module configured to generate a test pattern and a plurality of transmission multiplexers, each of which one input receives the test pattern;
the second die including a plurality of reception multiplexers and a second test module configured to control the plurality of reception multiplexers; and
a connection part including a plurality of signal transmission members electrically connected to outputs of the plurality of transmission multiplexers and each connected to one input of the reception multiplexers, and a robust transmission member configured to transmit a signal between the first test module and the second test module,
wherein the second test module transmits a signal, which is received by the reception multiplexer through the signal transmission member, to the first test module through the robust transmission member, and
the first test module detects a fault of the signal transmission member by comparing the test pattern with the signal transmitted by the second test module through the robust transmission member.

2. The stacked semiconductor apparatus of claim 1, wherein the transmission multiplexer further receives an internal signal of the first die and is controlled by the first test module to output the internal signal, and
the reception multiplexer further receives the internal signal and is controlled by the second test module to output the internal signal to the second die.

3. The stacked semiconductor apparatus of claim 1, wherein the first die further includes a bypass multiplexer to which outputs of the plurality of transmission multiplexers are provided and which is controlled by the first test module,
the connection part further includes a bypass transmission member connected to an output of the bypass multiplexer, and
the reception multiplexer is connected to the bypass connection member to further receive an output of the transmission multiplexer.

4. The stacked semiconductor apparatus of claim 3, wherein, when the fault of the signal transmission member is detected, the first test module controls the bypass multiplexer to output an output signal of a transmission multiplexer, which is connected to the signal transmission member in which the fault has occurred, to the bypass transmission member, and the second test module controls the reception multiplexer to receive the output signal of the transmission multiplexer from the bypass transmission member.

5. The stacked semiconductor apparatus of claim 3, wherein each of the signal transmission member and the bypass transmission member is one of a through-silicon via (TSV) and a bump, and
the bypass transmission member is disposed closer to a central portion of at least one of the first die and the second die than the signal transmission member.

6. The stacked semiconductor apparatus of claim 1, wherein the robust signal transmission member is one of a through-silicon via (TSV) and a bump and includes a plurality of transmission members configured to transmit the same signal.

7. The stacked semiconductor apparatus of claim 1, wherein the first die is a memory die, and
the second die is one of a logic die and a memory die.

8. A method of detecting a fault of a semiconductor apparatus including a first die and a second die which are stacked, the method comprising:
outputting, by the first die, a test pattern, which is formed by a first test module of the first die, through a plurality of signal transmission members;
receiving, by the second die, a signal from the plurality of signal transmission members;
outputting, by the second die, the received signal to the first test module through a robust transmission member; and
detecting, by the second test module, a fault of the signal transmission member from the signal provided by the second die,
wherein the robust transmission member includes a plurality of transmission members configured to transmit the same signal.

9. The method of claim 8, wherein the first die further includes a plurality of transmission multiplexers to which the test pattern is input and which are controlled by the first test module, and
the second die further includes a plurality of reception multiplexers to which a signal is input through the signal transmission member and which are controlled by the second test module.

10. The method of claim 9, wherein the outputting of the test pattern includes:
forming, by the first test module, the test pattern; and
outputting, by each of the transmission multiplexers, the test pattern to the signal transmission member.

11. The method of claim 9, wherein the receiving of the test pattern includes:
receiving, by each of the reception multiplexers, the signal from the signal transmission member; and
transmitting the signal received by the reception multiplexers to the second test module.

12. The method of claim 8, wherein the detecting of the fault is performed by comparing, by the first test module, the test pattern with a signal output by the second test module through the robust transmission member.

13. The method of claim 8, wherein each of the signal transmission member and the robust transmission member is one of a through-silicon via and a bump.

14. A method of repairing a stacking fault of a first die and a second die, the method comprising:
detecting, by a first test module, a fault of a plurality of signal transmission members configured to electrically connect the first die and the second die;
controlling, by the first test module, a bypass multiplexer to output an output of a multiplexer connected to a signal transmission member having the detected fault through a bypass transmission member; and
controlling, by a second test module, a reception multiplexer connected to the signal transmission member having the fault to output a signal provided through the bypass transmission member.

15. The method of claim 14, wherein the first die further includes the first test module configured to form the test pattern, and a plurality of transmission multiplexers to which the test pattern is input and which are controlled by the first test module, and
the second die further includes a plurality of reception multiplexers, which are identical to the reception multiplexer, to which each signal is input through the plurality of signal transmission members and which are controlled by the second test module.

16. The method of claim 14, wherein the detecting of the fault includes:
outputting, by the first test module of the first die, the test pattern to the plurality of signal transmission members;
receiving, by the second test module of the second die, a signal from the plurality of signal transmission members;
outputting the signal received by the second test module to the first test module through a robust transmission member; and
detecting, by the first test module, the fault of the plurality of signal transmission members from the signal provided from the second test module.

17. The method of claim 15, wherein an output of at least some of the transmission multiplexers is provided to an input of the bypass multiplexer, and
the bypass multiplexer is controlled by the first test module to provide an output to the bypass transmission member.

18. The method of claim 15, wherein each of the reception multiplexers further receives a signal provided through the bypass transmission member, and
the second test module controls a reception multiplexer connected to the signal transmission member having the fault to output the signal provided through the bypass transmission member.

19. The method of claim 14, wherein each of the bypass transmission member and the transmission member is one of a through-silicon via (TSV) and a bump, and
the bypass transmission member is disposed closer to a center of the first die and the second die than the signal transmission member.

20. The method of claim 14, wherein the first test module and the second test module are connected through a robust transmission member, and
the robust transmission member includes a plurality of transmission members configured to transmit the same signal.
